(19) United States
(12) Patent Application Publication
(10) Pub. No.: US 2025/0232943 A1
(43) Pub. Date: Jul. 17, 2025

(54) MULTIPLE PARTICLE BEAM SYSTEM WITH PROLONGED MAINTENANCE INTERVAL

(71) Applicant: Carl Zeiss MultiSEM GmbH, Oberkochen (DE)

(72) Inventors: Ticia Buhr, Braunschweig (DE); Yanko Sarov, Aalen (DE)

(21) Appl. No.: 19/011,273

(22) Filed: Jan. 6, 2025

(30) Foreign Application Priority Data
Jan. 11, 2024 (DE) 10 2024 100 717.6

(51) Int. Cl. H01J 37/09; H01J 37/20; H01J 37/26

(52) U.S. Cl. CPC H01J 37/09; H01J 37/20; H01J 37/261; H01J 2237/0453; H01J 2237/202

(57) ABSTRACT

A multiple particle beam system has an arrangement comprising a pre-aperture module and a micro-optical unit module. The pre-aperture module comprises a carrier plate with a first set comprising at least two multi-aperture arrays which are identical and thus have the same action, and have the same number of apertures, the same shape and size of the apertures and the same arrangement of the apertures and thus can be exchanged one for another. A mechanism for arranging the carrier plate in the particle-optical beam path makes it possible, in the event of damage to the active multi-aperture array in particular owing to x-ray radiation, to exchange multi-aperture arrays that have the same action. The micro-optical unit module, which is arranged downstream of the pre-aperture module in the particle-optical beam path, can be thereby better protected against x-ray radiation that occurs, and can have a longer service life.

### CROSS-REFERENCE TO RELATED APPLICATIONS

This application claims benefit under 35 U.S.C. § 119 to German Application No. 10 2024 100 717.6, filed Jan. 11, 2024. The entire disclosure of this application is incorporated by reference herein.

### FIELD

The disclosure relates in general to multiple particle beam systems that operate with a multiplicity of individual charged particle beams, such as multi-beam particle microscopes or lithography systems. Specifically, the disclosure relates to a multiple particle beam system with a prolonged maintenance interval.

### BACKGROUND

With the ongoing development of ever smaller and ever more complex microstructures such as semiconductor components, it is desirable further develop and optimize planar production techniques and inspection systems for producing and inspecting small dimensions of the microstructures. For instance, the development and production of the semiconductor components can involve monitoring of the design of test wafers, and the planar production techniques can involve process optimization for reliable production with high throughput. Moreover, there have been recent demands for an analysis of semiconductor wafers for reverse engineering and for a customized, individual configuration of semiconductor components. Therefore, it can be desirable to have an inspection mechanism which can be used with high throughput to examine the microstructures on wafers with high accuracy.

Typical silicon wafers used in the production of semiconductor components have diameters of up to 300 millimeters (mm). Each wafer is divided into 30 to 60 repeating regions (“dies”) with a size of up to 800 square millimeters (mm²). A semiconductor apparatus comprises multiple semiconductor structures, which are produced in layers on a surface of the wafer by planar integration techniques. Semiconductor wafers typically have a plane surface on account of the production processes. The structure dimension of the integrated semiconductor structures in this case extends from a few μm to the critical dimensions (CD) of a few nanometres, and the structure dimensions will become even smaller in the near future; the expectation is that in future the structure dimensions or critical dimensions (CD) will correspond to the 3 nanometers (nm), 2 nm or even smaller process nodes of the International Technology Roadmap for Semiconductors (ITRS). In the case of the aforementioned small structure dimensions, defects of the order of the critical dimensions are to be identified quickly over a very large area. For multiple applications, the desired accuracy of a measurement provided by inspection equipment can be even higher, for example by a factor of two or one order of magnitude. For instance, a width of a semiconductor feature re to be measured with an accuracy of below 1 nm, for example 0.3 nm or even less, and a relative position of semiconductor structures are to be determined with an overlay accuracy of below 1 nm, for example 0.3 nm or even less.

The mSEM, a multi-beam scanning electron microscope, is a relatively new development in the field of charged particle systems (charged particle microscopes, CPMs). For instance, a multi-beam scanning electron microscope is disclosed in U.S. Pat. No. 7,244,949 B2 and in US 2019/0355544 A1. In the case of a multi-beam electron microscope or mSEM, a sample is irradiated simultaneously by a multiplicity of individual electron beams arranged in a field or raster. For instance, 4 to 10,000 individual electron beams can be provided as primary radiation, with each individual electron beam being separated from an adjacent individual electron beam by a pitch of 1 to 200 micrometres (μm). For example, an mSEM has approximately 100 separate individual electron beams (“beamlets”), which are arranged for example in a hexagonal raster, with the individual electron beams being separated by a pitch of approximately 10 μm. The multiplicity of individual charged particle beams (primary beams) are focused through a common objective lens onto a surface of a sample to be examined. For example, the sample can be a semiconductor wafer which is secured to a wafer holder mounted on a movable stage. When the wafer surface is illuminated by the primary individual charged particle beams, interaction products, for example secondary electrons or backscattered electrons, emanate from the surface of the wafer. Their start points correspond to those locations on the sample onto which each one of the multiplicity of primary individual particle beams is focused. The amount and the energy of the interaction products generally depend on the material composition and the topography of the wafer surface. The interaction products form multiple secondary individual particle beams (secondary beams), which are collected by the common objective lens and, after passing through a projection imaging system of the multi-beam inspection system, are incident on a detector arranged in a detection plane. The detector comprises multiple detection regions, each of which comprises multiple detection pixels, and the detector captures an intensity distribution for each of the secondary individual particle beams. An image field of 100 μm×100 μm, for example, is obtained.

Certain known multi-beam electron microscopes comprise a sequence of electrostatic and magnetic elements. At least some of the electrostatic and magnetic elements can be adjusted in order to adapt the focus position and the stigmation of the multiplicity of individual charged particle beams. Such multi-beam systems with charged particles moreover can comprise at least one crossover plane of the primary or the secondary individual charged particle beams. Such systems can also comprise detection systems to make the adjustment easier. Such multi-beam particle microscopes can comprise at least one beam deflector (deflection scanner) for collective scanning of a region of the sample surface via the multiplicity of primary individual particle beams in order to obtain an image field of the sample surface.

What is known as a beam splitter (or alternatively beam separator or beam divider) is used to separate the particle-optical beam path of the primary beams from the particle-optical beam path of the secondary beams. Separation is effected via special arrangements of magnetic fields and/or electrostatic fields, for example via a Wien filter.

In the case of multiple particle beam systems, a distinction is made in general between systems that work with a single column and systems that work with multiple columns. In systems with a single column, the individual particle beams at least in part pass through the same particle-optical unit or through one or more global particle lenses. In addition, in a single column, the individual particle beams are relatively close to one another. Despite the partially global particle-optical elements, it can be desirable for individual influenceability and/or shapeability of the individual particle beams even in the case of single columns, in order to correct imaging aberrations such as image field curvature, field astigmatism and other aberrations. A so-called micro-optical unit can be used for this individual influencing and/or shaping of the individual particle beams. The micro-optical unit is often also referred to as a multi-beam particle generator for creating and shaping a plurality of individual particle beams. The multi-beam particle generator or the micro-optical unit comprises a sequence of several multi-aperture plates, which can be used for active beam shaping or of which at least one multi-aperture plate can be used for active beam shaping. Electrodes that can be actuated collectively or on an individual basis can be provided to this end for example in the region of the apertures. They can be, for example, ring electrodes or multi-pole electrodes. According to another example, a multi-aperture plate can have a monolithic form, with a voltage applied to the multi-aperture plate overall, i.e. the monolithic multi-aperture plate then is at a certain potential, and so its openings can create a lens effect in interaction with other particle-optical elements. Other configurations of a multi-aperture plate for active beam shaping are also possible.

To produce micro-optical units, use is made for example of MEMS techniques or planar integration techniques, i.e. the same processes also used for semiconductor production. The production of micro-optical units can be relatively slow and expensive, which is why an individual micro-optical unit is relatively valuable.

In the operation of multiple particle beam systems, the micro-optical unit can however be exposed to wear processes even when operated in high vacuum. Playing a part in this are not only charged particles that are incident on the micro-optical unit, such as electrons, but also secondary particles ejected from the micro-optical unit, and occurring x-ray radiation that is generated when charged particles strike the micro-optical unit. These particles and for example the x-ray radiation adversely affect the functioning of the micro-optical unit and the micro-optical unit becomes ruined in the long term and is to be exchanged. This exchange, in turn, can take a lot of time. The vacuum in the column of the multiple particle beam system is to be broken and then re-established. There is also the fact that adjustment work on the system can be involved owing to the implemented exchange of the micro-optical unit. The micro-optical unit is thus exchanged as seldom as possible.

U.S. Pat. No. 9,653,254 B2 discloses a multiple particle beam system which can enable straightforward adjustment of a beam current of individual particle beams. Disclosed for this purpose is a multi-aperture selector plate having multiple multi-aperture arrays, which is arranged on a movable carrier. The multi-aperture arrays are all different, specifically in terms of the aperture diameter and/or in terms of the number of apertures per array. By arranging the multi-aperture selector plate in the particle-optical beam path in different ways, different numbers of individual particle beams can thus be created and/or the individual beam diameter and thereby the individual beam current of the individual particle beams can thus be adjusted. U.S. Pat. No. 9,653,254 B2 does not discuss any issues in connection with wear processes and in particular in connection with x-ray radiation. The specific structure of a sequence of multi-aperture plates and their production is also not described in more detail.

DE 10 2020 115 183 A1 discloses a particle beam system with a multi-source system. The multi-source system comprises an electron emitter array as a particle multi-source. The inhomogeneous emission characteristics of the various emitters in this multi-source system are corrected, or pre-corrected for subsequent particle-optical imaging, via particle-optical components that are producible via MEMS technology. A beam current of the individual particle beams is adjustable in the multi-source system.

DE 10 2018 202 421 B3 discloses a multi-beam particle beam system comprising a multi-aperture plate having a multiplicity of apertures, one particle beam of the multiplicity of particle beams passing through each of the apertures during operation. A multiplicity of electrodes are provided isolated from the second multi-aperture plate in order to influence the particle beam passing through the aperture. A voltage supply system for the electrodes comprises a signal generator for generating a serial sequence of digital signals, a D/A converter for converting the digital signals into a sequence of voltages between an output of the D/A converter and the multi-aperture plate, and a controllable changeover system, which feeds the sequence of voltages one after another to different electrodes.

DE 10 2018 133 703 A1 discloses an apparatus for creating a multiplicity of particle beams comprising a particle source, a first multi-aperture plate with a multiplicity of openings, a second multi-aperture plate with a multiplicity of openings, a first particle lens, a second particle lens, a third particle lens and a controller, which supplies each of the first particle lens, the second particle lens and the third particle lens with an adjustable excitation.

DE 10 2018 007 652 A1 discloses a particle beam system for adjusting individual beam currents, comprising the following: at least one particle source, which is configured to create a beam of charged particles; a first multi-lens array, which comprises a first multiplicity of individually adjustable and focussing particle lenses and is arranged in the beam path of the particles in such a way that at least some particles pass through openings in the multi-lens array in the form of multiple individual particle beams; a second multi-aperture plate, which comprises a multiplicity of second openings and is arranged in the beam path of the particles downstream of the first multi-lens array and in such a way that, of particles which pass the first multi-lens array, some strike the second multi-aperture plate and some pass through the openings in the second multi-aperture plate; and a controller which is set up to supply an individually adjustable voltage to the particle lenses of the first multi-lens array and thus individually adjust the focussing of the associated particle lens for each individual particle beam.

DE 10 2014 008 083 A1 discloses a particle beam system comprising a particle source; a first multi-aperture plate with a multiplicity of openings, downstream of which particle beams are shaped; a second multi-aperture plate with a multiplicity of openings, through which the particle beams pass; an aperture plate with an opening through which all the particles that also pass through the openings in the first and the second multi-aperture plate pass; a third multi-aperture plate with a multiplicity of openings, through which the particle beams pass, and with a multiplicity of field generators, which provide a respective dipole field or quadrupole field for a beam; and a controller for supplying electrical potential to the multi-aperture plates and the aperture plate, such that the second openings in the second multi-aperture plate each act as a lens element on the particle beams, and for supplying adjustable excitations to the field generators.

### SUMMARY

The present disclosure seeks to provide a multiple particle beam system with a prolonged maintenance interval. For example, a micro-optical unit of the multiple particle beam system should have a longer service life and are to be exchanged less often. For example, it can be protected better against x-ray radiation. Optionally, it is possible to exchange the micro-optical unit overall more quickly.

Conventional high-performance micro-optical units are often produced by MEMS techniques. The micro-optical units can also comprise, besides the beam-shaping multi-aperture plates, a first individual-beam creating multi-aperture plate, what is referred to as the filter plate or pre-aperture plate. On this filter plate or pre-aperture plate, not only are the individual particle beams created as they pass through the filter plate, but also the incidence of high-energy charged particles on the filter plate also causes the generation of x-ray radiation, which damages firstly the filter plate but then also the other multi-aperture plates of the micro-optical unit and makes them unusable in the long term.

A concept of the disclosure is to decouple the filter plate, and make it exchangeable separately, from the actual, beam-shaping micro-optical unit. By exchanging the filter plate, the beam-shaping micro-optical unit overall, which is arranged downstream thereof in the particle-optical beam path, can be protected for longer against the damaging influences of the x-ray radiation and are to be exchanged less often. To this end, provided in the case of the multiple particle beam system according to the disclosure can be a modular structure with a pre-aperture module on the one hand and a micro-optical unit module on the other hand. The pre-aperture module in turn can comprise, so to say as a stock, a plurality of multi-aperture arrays that are identical and thus have the same action, and can be used successively as filter arrays. It is possible to exchange the multi-aperture arrays without breaking the vacuum in the multiple particle beam system principle until the stock of multi-aperture arrays is exhausted.

According to a first aspect, the disclosure provides a multiple particle beam system comprising the following:
a particle source for emitting charged particles;
a pre-aperture module comprising
a carrier plate, wherein the carrier plate has a first set with at least two identical multi-aperture arrays which have the same number N of apertures, the same shape and size of the apertures and the same arrangement of the apertures and thus can be exchanged one for another,
a holding element for the carrier plate, and
a mechanism for arranging, in particular displacing, the carrier plate in the particle-optical beam path and for exchanging the at least two identical multi-aperture arrays in the particle-optical beam path one for another,
wherein, during operation of the multiple particle beam system, the carrier plate is arranged in the particle-optical beam path of the multiple particle beam system such that the charged particles emitted by the particle source are incident on only one of the at least two multi-aperture arrays and pass through it to form a multiplicity of first individual particle beams N; and
a micro-optical unit module, which is arranged downstream of the pre-aperture module in the particle-optical beam path and comprises the following:
a sequence of multiple multi-aperture plates, which form the micro-optical unit and are arranged fixedly relative to one another, and
a micro-optical holder for holding the micro-optical unit,
wherein, during operation of the multiple particle beam system, the apertures in the multi-aperture plates are each passed through by exactly one of the individual particle beams and wherein the micro-optical unit particle-optically shapes the multiplicity of first individual particle beams.

The multiple particle beam system may be for example a multi-beam inspection system, in particular a multi-beam particle microscope. It may, however, also be a lithography system or another multiple particle beam system. It can be a multiple particle beam system operating with a single column.

The multiple particle beam system has at least one particle source for emitting charged particles, for example electrons, positrons, muons or ions.

The carrier plate with the at least two identical multi-aperture arrays can form a core of the pre-aperture module. A respective multi-aperture array can take on the function of the filter plate as described above in connection with the description of the prior art. The multi-aperture array currently arranged in the particle-optical beam path can thus create the multiplicity of first individual particle beams. The carrier plate with the respective active multi-aperture array, which is to say with the respective multi-aperture array that is arranged in the particle-optical beam path, is the first, as calculated from the particle source, multi-aperture unit or multi-aperture plate which can be used to form the first individual particle beams. As a result, the charged particles incident on the multi-aperture array can be incident there in very large numbers. According to an embodiment of the disclosure, more than 90% of all particles incident on the multi-aperture array are absorbed there and then discharged. According to an embodiment variant, it is more than 95% or more than 98% of the charged particles. Upon this striking of the multi-aperture array by the particles, there secondary particles are ejected from the carrier plate and x-ray radiation is produced. Both of these result in damage to the carrier plate and also structures arranged therebeneath. The damage to structures arranged therebeneath can be all the greater the greater the damage to the carrier plate or the damage in the active multi-aperture array is. By exchanging the multi-aperture array in the particle-optical beam path, the service life of the pre-aperture module and thus also its protective function for the underlying actual micro-optical unit or the micro-optical unit module can be prolonged. The micro-optical unit module thus does not need to be exchanged as frequently. This can be sustainable, save time and cut back on costs.

The mechanism for arranging the carrier plate in the particle-optical beam path can be realized in different ways. It may be formed in one part or in multiple parts. It is possible for the mechanism to be operated by hand. The mechanism can be electronically actuatable. This allows a more precise positioning of the carrier plate, with the identical multi-aperture-arrays thereon, in the particle-optical beam path.

The term arranging in connection with the present patent application is merely understood to mean that selectively one of the identical multi-aperture arrays can be introduced into the particle-optical beam path. This introduction may involve a displacement of the carrier plate, but may also involve a rotation of the carrier plate, etc. The term exchanging two identical multi-aperture arrays in the particle-optical beam path one for another means only that the two multi-aperture arrays are functionally exchanged: the one multi-aperture array is active, the other is not. It does not automatically mean that the positions of the two multi-aperture arrays are exchanged exactly for one another.

The micro-optical unit module according to the present disclosure comprises a sequence of multiple multi-aperture plates, which form the (beam-shaping) micro-optical unit and are arranged fixedly relative to one another. This fixed arrangement defines the module-like character of the micro-optical unit module. By definition, it is not possible for one of the multi-aperture plates of the micro-optical unit module to be exchanged separately during the operation or a short pause in operation of the multiple particle beam system. Rather, it is such that the sequence of multiple multi-aperture plates, or the micro-optical unit, is produced before being installed in the multiple particle beam system as a module.

According to the disclosure, the micro-optical unit particle-optically shapes the multiplicity of first individual particle beams. The micro-optical unit is thus an active micro-optical unit, which is to say the particle-optical beam path of the first individual particle beams is actively influenced by the micro-optical unit. The individual particle beams can be for example focussed, deflected, provided with a stigmation, or the like. Particle-optical shaping via the micro-optical unit does not, however, mean creating the first individual particle beams. This is done instead via the pre-aperture module and the multi-aperture arrays arranged in the carrier plate.

According to an embodiment of the disclosure, the micro-optical unit has a multi-stigmator unit and/or the micro-optical unit has a multi-lens array. The multi-stigmator unit may be realized for example as a multi-aperture plate, with individually actuatable multi-pole electrodes being provided in the region of the apertures. The multi-lens array may be realized for example as a multi-aperture plate, with ring electrodes being arranged around its openings. However, other embodiments for these active elements of the micro-optical unit for particle-optical beam shaping are also possible.

According to an embodiment of the disclosure, the sequence of multi-aperture plates has a first multi-aperture plate, which is the first multi-aperture plate in the particle-optical beam path of the multiple particle beam system through which the first individual particle beams formed in the pre-aperture module pass. The dimensions of the apertures in the first multi-aperture plate can be provided such that the first individual particle beams pass through the apertures in the first multi-aperture plate without contact. The first multi-aperture plate of the micro-optical unit is thus in functional terms not a filter plate. Since the first individual particle beams pass through the apertures in the first multi-aperture plate without contact, charged particles do not strike this first multi-aperture plate and there is no formation of secondary particles or x-ray radiation. This can protect the micro-optical unit against contamination and destruction by these/this secondary particles/secondary radiation.

According to an embodiment of the disclosure, the holding element for the carrier plate is fixedly connected to or integrated in the micro-optical unit holder for the micro-optical unit. This ensures a fixed reference during the relative positioning of the pre-aperture module relative to the micro-optical unit module. They are to be aligned exactly relative to one another in order to be able to interact with one another in functionally exact terms.

For example, the midpoints of apertures in a multi-aperture array in the carrier plate would have to be aligned with the midpoints of apertures in the sequence of multi-aperture plates of the micro-optical unit exactly relative to one another.

According to an embodiment of the disclosure, the micro-optical unit holder has a flange, via which the micro-optical unit holder is sealingly installed in the multiple particle beam system. During operation, normally a vacuum or high vacuum prevails in the multiple particle beam system. The sealing installation of the micro-optical unit via the micro-optical unit holder is thus important in that case. A flange makes it possible to readily realize this.

According to an embodiment of the disclosure, the holding element for the carrier plate is passed through the flange. The holding element for the carrier plate can thereby also mounted in the flange. Moreover, this can be such that this feedthrough is vacuum-tight. In this embodiment, the holding element for the carrier plate is thus integrated in the micro-optical unit holder or the flange.

According to an embodiment of the disclosure, the pre-aperture module furthermore has a lower aperture plate with a singular central opening, which is arranged in the particle-optical beam path between the carrier plate and the micro-optical unit module such that, during operation of the multiple particle beam system, the first individual particle beams pass through the opening in the lower aperture plate without contact. This lower aperture plate serves according to the disclosure, among other things, as a shield plate. Secondary particles and x-ray radiation generated when the charged particles from the particle source strike the active multi-aperture array normally have different directions, or scattering angles. A large proportion of the generated secondary particles and/or x-ray radiation which has a direction component towards the micro-optical unit module can thus strike this lower aperture plate. As a result, the micro-optical unit of the micro-optical unit module is even better protected. The contactless passage through the lower aperture plate is important for two reasons. Firstly, the first individual particle beams have already been created in the pre-aperture module. Cutting off or attenuating some individual particle beams is therefore counter-productive. Secondly, a non-contactless striking of the lower aperture plate would in turn ensure that secondary particles and x-ray radiation are generated, and this in turn would have an adverse effect on the service life of the micro-optical unit.

According to an embodiment of the disclosure, the material of the lower aperture plate is x-ray absorbing. It can comprise copper. The lower aperture plate can be approximately between 1 mm and 1.5 mm thick. In addition or as an alternative, it is possible for the lower aperture plate to have an x-ray absorbing coating. Such a coating can comprise for example a gold coating, for the thickness d_{AU} of which it holds true, for example, that 3 μm≤d_{AU}≤50 μm, such as 5 μm≤d_{AU}≤20 μm. A gold coating may be applied by sputtering or galvanically. In addition or as an alternative, it is also possible for the x-ray absorbing layer to have a thin film or layer comprising copper, tantalum and/or titanium, wherein for the thickness dₛ of this layer it holds true for example that 0.1 mm≤dₛ≤1.0 mm, such as 0.25 mm≤dₛ≤0.75 mm.

According to an embodiment of the disclosure, for a pitch D2 between the lower aperture plate and the uppermost multi-aperture plate of the multi-optical unit module, the following relationship holds true: D2≥0.5 cm, such as D2≥1.0 cm or D2≥5.0 cm. The uppermost multi-aperture plate may be identical to the first multi-aperture plate of the micro-optical unit. The pitch D2 between the lower aperture plate of the pre-aperture module, on the one hand, and the uppermost multi-aperture plate of the micro-optical unit module, on the other hand, is a measure of the pitch between the pre-aperture module and the micro-optical unit module. Owing to the modular layout for the individual beam formation, on the one hand, and the particle-optical shaping of the individual particle beams, on the other hand, this pitch can be selected to be greater than in the case of a non-modular way of creating individual beams and shaping individual beams. A multiple particle beam system according to the disclosure as a result can have one more flexibly selectable parameter than conventional multiple particle beam systems do. A relatively large pitch D2 moreover can have the result that the shielding action or protective action of the pre-aperture module for the micro-optical unit module can be even further improved. In the case of a larger pitch D2, it is possible to prevent even more secondary particles and even more x-ray radiation from reaching the micro-optical unit itself.

According to an embodiment of the disclosure, the pre-aperture module furthermore has an upper aperture plate with a singular central opening, which is arranged in the particle-optical beam path above the carrier plate such that the charged particles from the particle source completely or partially pass through the central opening in the upper aperture plate. By contrast to the lower aperture plate, in the case of the upper aperture plate it is not per se damaging to the micro-optical unit further downstream in the particle-optical beam path if secondary particles and x-ray radiation are generated on the upper aperture plate. The upper aperture plate can be considerably further away from the micro-optical unit than the lower aperture plate of the pre-aperture module is. It is, however, also possible for the charged particles from the particle source to pass through the central opening in the upper aperture plate completely and thus without contact, without producing secondary particles or x-ray radiation.

According to an embodiment of the disclosure, the material of the upper aperture plate is x-ray absorbing. It can comprise copper. The thickness of the upper aperture plate can be at least 1 mm. In addition or as an alternative, it is possible for the upper aperture plate to have an x-ray absorbing coating. Such a coating can comprise for example a gold coating, for the thickness d_{AU} of which it holds true, for example, that 3 μm≤d_{AU}≤50 μm, such as 5 μm≤d_{AU}≤20 μm. The gold coating may be applied by sputtering or galvanically. In addition or as an alternative, it is also possible for the x-ray absorbing layer to have a thin film or layer comprising copper, tantalum and/or titanium, wherein for the thickness dₛ of this layer it holds true for example that 0.1 mm≤dₛ≤1.0 mm, such as 0.25 mm≤dₛ≤ 0.75 mm.

According to an embodiment of the disclosure, the upper aperture plate and the lower aperture plate form walls of a pre-aperture chamber for the carrier plate and the opening in the upper aperture plate and/or the lower aperture plate is/are closable in vacuum-tight fashion. For this, it is possible to provide for example a vacuum gate valve in the region of the singular openings in the upper or lower aperture plate. This can help make it possible to close the pre-aperture chamber in vacuum-tight fashion in both directions, that is to say both towards the particle source and towards the micro-optical unit. If the carrier plate with the at least two identical multi-aperture arrays comes specifically to the end of its service life, i.e. all identical multi-aperture arrays are damaged, the carrier plate is to be exchanged. In the case of the embodiment variant described, it is then possible to firstly close the pre-aperture chamber in the particle-optical beam path in vacuum-tight fashion and then break the vacuum only in the pre-aperture chamber. Then, the carrier plate can be taken out of the pre-aperture chamber and exchanged for a new carrier plate with new identical multi-aperture arrays. It is furthermore possible to then re-evacuate and/or bake the pre-aperture chamber. After that, the openings in the upper aperture plate and/or the lower aperture plate can be opened up again. An exchange of the carrier plate performed in this way can take place more quickly than an exchange of the entire pre-aperture module or even an exchange of the entire micro-optical unit module. Moreover, this procedure is more resource-conserving.

According to an embodiment of the disclosure, the pre-aperture chamber is accessible from outside the multiple particle beam system. This can help facilitate the above-described exchange of the carrier plate, without needing to exchange the entire pre-aperture module.

According to an embodiment of the disclosure, the carrier plate is displaceable linearly in a direction orthogonal to the particle-optical beam path. The carrier plate can thus be displaced for example from left to right.

According to an embodiment of the disclosure, the carrier plate is displaceable with two degrees of freedom within a plane oriented orthogonally to the particle-optical beam path. According to one example, the carrier plate is thus displaceable not only from left to right, but for example also from front to back (x and y direction, when the particle-optical beam path coincides with the z direction).

According to an embodiment of the disclosure, the carrier plate is displaceable along the direction of the particle-optical beam path. The carrier plate thus comprises a mechanism for height adjustment along the particle-optical beam path. This is an additional degree of freedom which makes it possible, for example, to use the pre-aperture module according to the disclosure in combination with a multiplicity of differently configured micro-optical unit modules.

According to an embodiment of the disclosure, the multi-aperture arrays of the carrier plate can be introduced into the particle-optical beam path via a carousel or revolver system. Also this embodiment variant of the disclosure makes the exchangeability of functionally identical multi-aperture arrays possible.

According to an embodiment of the disclosure, the apertures in the two functionally identical multi-aperture arrays are round or elliptical. In addition or as an alternative, the apertures in the two multi-aperture arrays have a field profile. In this case, for example the radii of round apertures in the multi-aperture arrays are not all identical. For example, the radius of the apertures can depend on how far away the aperture is from the central one of the individual particle beams (radial dependence). The same can apply to the ellipticity of the apertures. It is, however, also possible for the described field profile to be Cartesian, for example vary from left to right and/or from front to back.

According to an embodiment of the disclosure, the carrier plate has at least one second set with at least two identical multi-aperture arrays. In the case of this second set, the at least two identical multi-aperture arrays are in turn functionally identical, which is to say the number of apertures is identical, the shape of the apertures and the size of the apertures are identical and the apertures have overall the same arrangement in the multi-aperture array. According to the disclosure, the apertures in the multi-aperture arrays of the first set differ from the apertures in the multi-aperture arrays of the second set. The first set of the carrier plate can differ from the second set of the carrier plate for example by the radius of the apertures. In this way, it is possible not only to prolong the service life of the micro-optical unit of the multiple particle beam system but also to vary the beam current of the individual particle beams: In the case of large apertures, this beam current is high; in the case of small apertures, it is low. Moreover, it is for example possible for the first set to be provided with round apertures in the multi-aperture arrays and for the second set to be provided with elliptical apertures in the multi-aperture arrays. Other configuration variants are also possible.

In addition, the carrier plate may have a third or further set with likewise at least two functionally identical multi-aperture arrays. However, it is not advisable to provide too many sets in the carrier plate. Specifically, there is the risk that not every set is in fact completely utilized or exhausted through to the end of the service life of the carrier plate.

According to an embodiment of the disclosure, the multiple particle beam system furthermore has at least one further micro-optical unit module, which is arranged within a vacuum, but outside the particle-optical beam path of the multiple particle beam system. Furthermore, the multiple particle beam system has an exchanging mechanism for exchanging the micro-optical unit module for the further micro-optical unit module under vacuum. In the case of this embodiment variant of the disclosure, therefore, the further micro-optical unit module is already provided, so to say in a stock, under vacuum in the multiple particle beam system. If it is desirable to exchange the micro-optical unit module for the further micro-optical unit module, this can be done more quickly, because it does not require breaking a vacuum in the multiple particle beam system.

According to an embodiment of the disclosure, the multiple particle beam system has a storage chamber, in which the at least one further micro-optical unit module is arranged. The storage chamber is separated from the vacuum inside the multiple particle beam system via a lock. This lock can help protect the further micro-optical unit even better against x-ray radiation and in particular also against secondary radiation produced inside the multiple particle beam system. Through the lock, the active micro-optical unit module can be exchanged for the further micro-optical unit module.

According to an embodiment of the disclosure, the storage chamber has an outer door and/or the storage chamber has a vacuum and ventilation unit for generating a vacuum in the storage chamber or ventilating the storage chamber. Through this outer door, it is possible during operation of the multiple particle beam system to remove a defective or spent micro-optical unit module and introduce a new, unspent micro-optical unit module into the storage chamber. This does not disrupt the ongoing operation of the multiple particle beam system. During operation of the multiple particle beam system, the vacuum and ventilation unit can furthermore be used to then generate a vacuum in the storage chamber. In this way, an unspent micro-optical unit module is available more quickly for exchange under vacuum in the multiple particle beam system.

According to an embodiment of the disclosure, the storage chamber furthermore has a heating element for baking the storage chamber and/or the storage chamber has a plasma cleaning unit for cleaning a stored micro-optical unit module and/or an exchanged micro-optical unit module. The heating element can help allow for quicker establishment of a vacuum or high vacuum in the storage chamber. The plasma cleaning unit can reduce the introduction of contaminations on a micro-optical module into the particle-optical beam path of the multiple particle beam system. Moreover, it is possible that, through the plasma cleaning unit, an already exchanged micro-optical unit module can be put back into a state in which it can be utilized for some time, without errors, in the multiple particle beam system.

Of course, it is also possible not only to exchange the micro-optical unit module in the way described, but also to exchange the combination of pre-aperture module and micro-optical unit module in the way described. Depending on the structural configuration of the pre-aperture module and the micro-optical unit module, this can be desirable or even necessary for an exchange. Moreover, it is possible to also exchange a micro-optical unit, including filter plate, that is already known from the prior art in this way. This could then, however, on the whole be less sustainable, and therefore, for individual particle beam formation and shaping, the modular structure with pre-aperture module and micro-optical unit module can be desirable.

### BRIEF DESCRIPTION OF THE DRAWINGS

The disclosure will be understood even better with reference to the accompanying figures. In the figures:

FIG. 1: schematically shows a multiple particle beam system;

FIG. 2: schematically shows a structure of a micro-optical unit with filter plate;

FIGS. 3A-3B: schematically show an arrangement with a pre-aperture module and with a micro-optical unit module;

FIGS. 4A-4B: schematically show an arrangement with a pre-aperture module and with a micro-optical unit module;

FIGS. 5A-5C: schematically show multiple carrier plates with multi-aperture arrays;

FIGS. 6A-6B: schematically shows multiple carrier plates with multi-aperture arrays;

FIG. 7: schematically shows a carrier plate with multi-aperture arrays;

FIG. 8: schematically shows an arrangement with a pre-aperture module and with a micro-optical unit module;

FIGS. 9A-9B: schematically show a multiple particle beam system with a storage chamber for a micro-optical unit module; and

FIGS. 10A-10D: schematically show a multiple particle beam system with a storage chamber for a micro-optical unit module.

### DETAILED DESCRIPTION

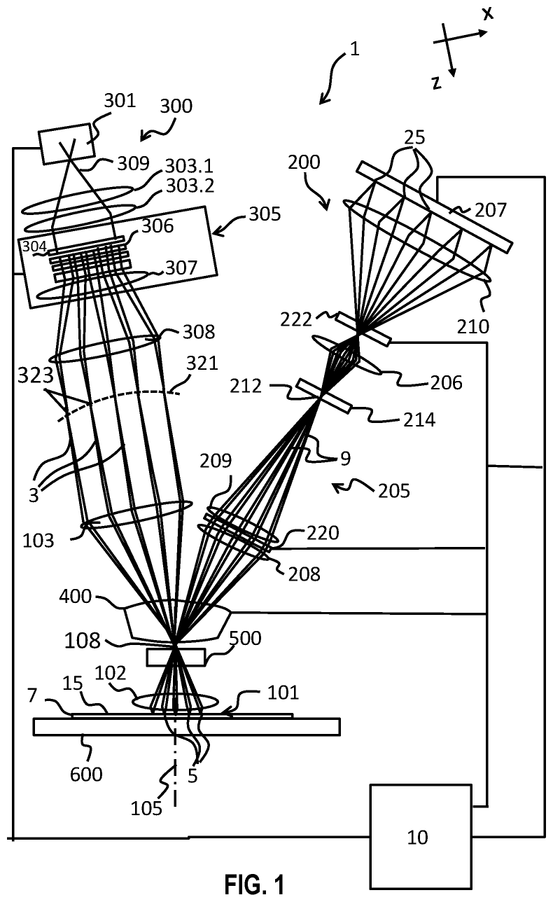

FIG. 1 schematically shows a multiple particle beam system 1 in the form of a multi-beam particle microscope 1. The multi-beam particle microscope 1 comprises a beam generating apparatus 300 having a particle source 301, for example an electron source. A divergent particle beam 309 is collimated by a sequence of condenser lenses 303.1 and 303.2 and incident on a multi-aperture arrangement 305, which forms a micro-optical unit. The multi-aperture arrangement 305 comprises several multi-aperture plates 306 and a field lens 308. A plurality of individual particle beams 3 or individual electron beams 3 are created by the multi-aperture arrangement 305. Midpoints of apertures in the multi-aperture plate arrangement are arranged in a field which is imaged on a further field formed by beam spots 5 in the object plane 101. The pitch between the midpoints of apertures in a multi-aperture plate 306 can be for instance 5 μm, 100 μm and 200 μm. The diameters D of the apertures are smaller than the pitch of the midpoints of the apertures; examples of the diameters are 0.2 times, 0.4 times and 0.8 times the pitches between the midpoints of the apertures.

The multi-aperture arrangement 305 and the field lens 308 are configured to generate a plurality of focal points 323 of primary beams 3 in a raster arrangement on a surface 321. The surface 321 need not be a plane surface but rather can be a spherically curved surface in order to account for an image field curvature of the subsequent particle-optical system.

The multi-beam particle microscope 1 further comprises a system of electromagnetic lenses 103 and an objective lens 102, which image the beam foci 323 from the intermediate image surface 325 in the object plane 101 with reduced size. In between, the first individual particle beams 3 pass through the beam splitter 400 and a collective beam deflection system 500, via which the plurality of the first individual particle beams 3 are deflected during operation and the image field is scanned. The first individual particle beams 3 incident in the object plane 101 form for example a substantially regular field, wherein the pitch between adjacent incidence locations 5 can be for example 1 μm, 10 μm or 40 μm. The field formed by the incidence locations 5 can have for example a rectangular or hexagonal symmetry.

The object 7 to be examined can be of any desired type, for instance a semiconductor wafer or a biological sample, and can comprise an arrangement of miniaturized elements or the like. The surface 15 of the object 7 is arranged in the object plane 101 of the objective lens 102. The objective lens 102 can comprise one or more electron-optical lenses. It can be for example a magnetic objective lens and/or an electrostatic objective lens.

The primary particles 3 incident on the object 7 generate interaction products, for example secondary electrons, backscattered electrons or primary particles, which have experienced a reversal of movement for other reasons, and these interaction products emanate from the surface of the object 7 or from the first plane 101 or object plane 101. The interaction products emanating from the surface 15 of the object 7 are shaped by the objective lens 102 to form secondary particle beams 9. In the process, the secondary beams 9 pass through the beam splitter 400 downstream of the objective lens 102 and are supplied to a projection system 200. The projection system 200 comprises an imaging system 205 with projection lenses 208, 209 and 210, a contrast stop 214 and a multi-particle detector 207. Incidence locations 25 of the second individual particle beams 9 on detection regions of the multi-particle detector 207 are located with a regular pitch in a third field. Exemplary values are 10 μm, 100 μm and 200 μm.

The multi-beam particle microscope 1 further comprises a computer system or a control unit 10, which in turn can have a single-part or multi-part design and which is designed both to control the individual particle-optical components of the multi-beam particle microscope 1 and to evaluate and analyse the signals obtained by the multi-detector 207 or the detection unit.

Further information relating to such multi-beam particle beam systems or multi-beam particle microscopes 1 and component parts used therein, such as particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is fully incorporated by reference in the present application.

The multi-aperture arrangement 305 comprises multiple multi-aperture plates for creating the individual particle beams 3 and for particle-optically shaping the multiple particle beams. The multi-aperture arrangement 305 may have a modular construction and comprise an arrangement according to the disclosure with a pre-aperture module 370 and a micro-optical unit module as described above in several embodiment variants.

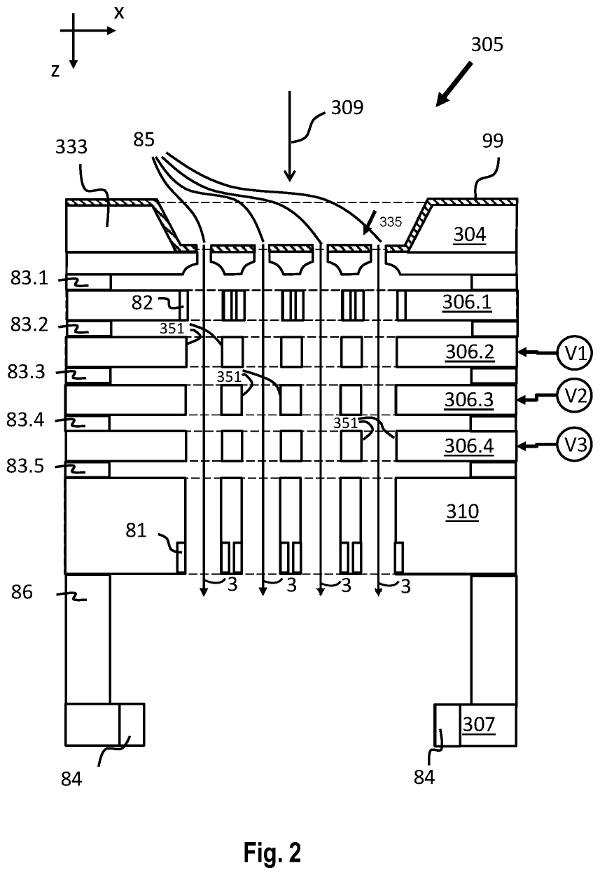

FIG. 2 shows, by way of example, a micro-optical unit 305 which is in the form of a multi-beam generator 305. In the illustrated example, the multi-beam generator 305 comprises a sequence with six multi-aperture plates 304, 306.1, 306.2, 306.3, 306.4 and 310 and a global condenser lens 307 in the z direction, which corresponds to the direction of propagation of the individual particle beams 3. Each of the multi-aperture plates 304, 306.1 to 306.4 and 310 comprises a plurality of apertures 351, through which the plurality of individual particle beams 3 respectively pass. The cross section through the apertures 351 is not to scale in FIG. 2.

The plurality of multi-aperture plates 304, 306.1, 306.2, 306.3, 306.4 and 310 are spaced apart from one another by spacers 83.1 to 83.5. Moreover, a spacer 86 is provided between the final multi-aperture plate 310 and the global lens electrode 307. As a result of the incidence of a collimated particle or electron beam 309, the plurality of first individual particle beams 3 are created during the passage through the first multi-aperture plate 304, which is also referred to as filter plate or pre-aperture plate. The pre-aperture plate 304 comprises a metal layer 99 on its beam input side, for stopping and absorbing the charged particles, or electrons, of the electron beam 309 that are incident thereon around the plurality of apertures 85. The material of the pre-aperture plate 304 is produced in the example shown from a conductive material, for example from doped silicon, and is at earth potential.

In the example shown in FIG. 2, the next multi-aperture plate is a multi-stigmator plate 306.1. The multi-stigmator plate 306.1 comprises a plurality of four or more electrodes 82, for example eight electrodes for each of the apertures. During the operation of the multi-beam particle microscope 1, different voltages, for example ranging between −20 V and +20 V, can be applied to each of these electrodes and hence individually influence each individual particle beam 3. For example, it is possible with an antisymmetric voltage difference to deflect each individual particle beam 3 up to a few μm in each direction in order to pre-correct a distortion of the illuminating unit 100. An astigmatism pre-correction for each individual particle beam 3 can be undertaken in this way. Via an offset voltage, each multi-pole element can additionally act as an Einzel lens.

In general, the multi-aperture plates 306.2, 306.3 and 306.4 can be any desired trajectory correction plates with monolithic design and with a respective voltage V1, V2 and V3 applied thereto in the example shown. It is also possible that the multi-aperture plates 306.2, 306.3 and 306.4 form an Einzel lens array. Different apertures 351 in the same multi-aperture plate 306.2, 306.3 and 306.4 can have an identical design or different design, for example have different diameters in order to take into account a field dependence of the correction in the trajectory correction of the individual particle beams 3.

The multi-aperture plate 310 is a two-layer multi-aperture plate and comprises a plurality of ring electrodes 79 for the plurality of apertures, wherein each ring electrode is configured to individually change or correct a focal position of the first individual particle beam 3 passing therethrough. The upper layer is insulated from the layer, or ply, with the ring electrodes 79 and produced from a conductive material such as doped silicon.

The field lens 307 comprises a ring electrode 84, to which a high voltage of for example 3 kV to 20 kV can be applied, for example 12 kV to 17 kV. In the example shown, the condenser lens 307 provides a global electrostatic lens field for global focussing of the plurality of individual particle beams 3.

The micro-optical unit 305 or its multi-aperture plates shown in FIG. 2 can in general be produced via known production methods or via planar integration techniques. A characterizing feature of the micro-optical unit 305 is that the micro-optical unit 305 comprises the filter plate 304, with the result that the multiplicity of first individual particle beams 3 is created in the first place via the micro-optical unit 305. Owing to the incidence of charged particles such as electrons on the filter plate 304, however, not only are the first individual particle beams 3 created, but there is also generation of x-ray radiation, which damages on the one hand the filter plate 304 itself and on the other hand also the rest of the multi-aperture plates 306.1, 306.2, 306.3, 306.4 and 310 of the micro-optical unit 305 and the conductor tracks/electrodes arranged thereon and makes them unusable over time. In such a case, the entire micro-optical unit 305 illustrated in FIG. 2 is to be exchanged in the course of maintenance on the multiple particle beam system.

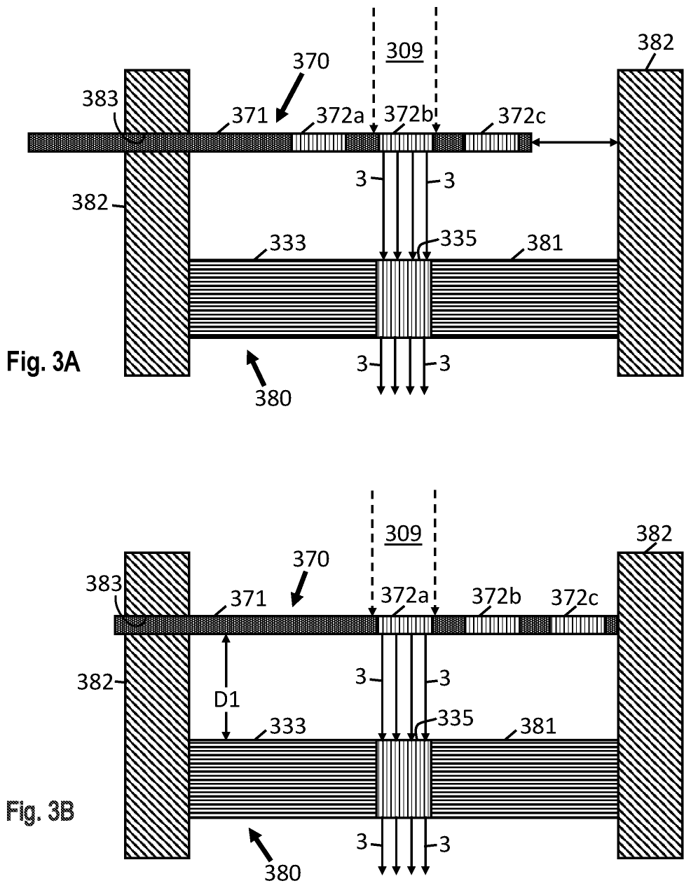

FIGS. 3A-3B illustrate, via a first exemplary embodiment, an arrangement for creating the individual particle beams 3 and particle-optically shaping them: The arrangement schematically illustrated in FIGS. 3A-3B comprises a pre-aperture module 370 and a micro-optical unit module 380. The pre-aperture module 370 comprises a carrier plate 371, the carrier plate 371 having a set of three identical multi-aperture arrays 372a, 372b and 372c. The three multi-aperture arrays 372a, 372b and 372c can be functionally exchanged one for another and have the same action in functional terms. This means that the multi-aperture arrays 372a, 372b and 372c have the same number N of apertures, the same shape and size of the apertures and the same arrangement of the apertures. Its action for shaping the first individual particle beams 3 is thus identical. The carrier plate 371 can be arranged, or displaced, in the particle-optical beam path in various ways. This is illustrated by the double-headed arrow in FIG. 3A. The carrier plate 371 is therefore, during operation of the multiple particle beam system 1, arranged in the particle-optical beam path of the multiple particle beam system 1 such that the charged particles-illustrated by the particle beam 309—emitted by the particle source 301 (not illustrated) are incident on only one of the three multi-aperture arrays 372a, 372b and 372c and pass through it to form a multiplicity of first individual particle beams 3.

The micro-optical unit module 380 is arranged downstream of the pre-aperture module 370 in the particle-optical beam path. It has a sequence of multiple multi-aperture plates, which form the micro-optical unit and are arranged fixedly relative to one another. The sequence of multi-aperture plates is not illustrated in detail in FIGS. 3A-3B; instead, this sequence is illustrated only as a block with a membrane region 335 and a holding region 333. The apertures in the multi-aperture plates of the micro-optical unit module 380 are each passed through by exactly one of the individual particle beams 3 during operation of the multiple particle beam system 1, with the result that the micro-optical unit particle-optically shapes the multiplicity of first individual particle beams 3. For example, the sequence of multi-aperture plates may be the sequence of multi-aperture plates 306.1, 306.2, 306.3, 306.4 and 310, which was illustrated by way of example in FIG. 2. However, this sequence does not include a filter plate 304. According to one embodiment, the micro-optical unit has a multi-stigmator unit and/or the micro-optical unit has a multi-lens array.

When the charged particles of the particle beam 309 are incident on the respective multi-aperture array 372a, 372b or 372c that is active, i.e. located in the particle-optical beam path, on the one hand secondary particles are produced and on the other hand x-ray radiation is formed. These secondary particles and in particular the x-ray radiation damage firstly the active multi-aperture array 372 and, to a certain extent, also the multi-aperture plate sequence of the micro-optical unit module 380. If, in the case of the arrangement according to the disclosure of the pre-aperture module 370 and the micro-optical unit module 380, the damage to the active multi-aperture array 372a, 372b and 372c then has progressed to an extent that the multi-aperture array 372a, 372b, 372c can no longer be used further to create particle beams, it is therefore to be exchanged. According to the disclosure, this exchange is then brought about in that an identical multi-aperture array 372a, 372b and 372c is introduced into the particle-optical beam path through a changed arrangement of the carrier plate 371: In FIG. 3A, the multi-aperture array 372b is active. If it is to be exchanged, the carrier plate 371 can be displaced such that, instead of the multi-aperture array 372b, the still unspent multi-aperture array 372a is introduced into the particle-optical beam path. In this way, the underlying micro-optical unit module 380 can be protected for longer. In the course of exchanging the defective multi-aperture array 372b, it is moreover not necessary to conjointly exchange the micro-optical unit module 380. If the carrier plate comprises three identical multi-aperture arrays 372a, 372b and 372c, the period of time until the entire arrangement of pre-aperture module 370 and micro-optical unit module 380 is exchanged can be approximately tripled in length. The more multi-aperture arrays 372 with the same structure or the same action are integrated in the carrier plate 371, the longer the time interval can be between two maintenance operations owing to the exchange of constituent parts of the arrangement with the pre-aperture module 370 and the micro-optical unit module 380.

In the exemplary embodiment shown in FIGS. 3A-3B, the micro-optical unit is held via a micro-optical unit holder 382. The micro-optical unit holder 382 can comprise, for example, a flange. The membrane region 335 corresponds to the micro-optical unit, strictly speaking. The membrane region 335 performs the beam shaping of the first individual particle beams 3 that were already formed beforehand. In the exemplary embodiment shown, the micro-optical unit holder 382 has a feedthrough 383, through which the carrier plate 371 of the pre-aperture module 370 is passed. In the region of this feedthrough 383, the micro-optical unit holder 382 thus serves at the same time also as a holding element for the carrier plate 371.

The mechanism for arranging the carrier plate 371 in the particle-optical beam path is not explicitly illustrated in FIGS. 3A-3B. Instead, only the linear movement direction is indicated by the double-headed arrow in FIG. 3B. The mechanism may be for example a linear drive, which is for example electrically actuatable. However, other embodiment variants are also possible.

In the exemplary embodiment illustrated in FIGS. 3A-3B, it is furthermore the case that the sequence of multi-aperture plates of the micro-optical unit 335 has a first multi-aperture plate (not denoted separately), which is the first multi-aperture plate in the particle-optical beam path of the multiple particle beam system 1 through which the first individual particle beams 3 formed in the pre-aperture module 370 pass. The dimensions of the apertures in this first multi-aperture plate are provided such that the first individual particle beams 3 pass through the apertures in the first multi-aperture plate without contact. Therefore, charged first particle beams 3 do not strike the first or uppermost multi-aperture plate of the micro-optical unit 335. There is thus no formation of secondary particles and in particular no formation of x-ray radiation there. The formation of x-ray radiation is thereby delimited to a different location, specifically in the region of the pre-aperture module 370. This protects the micro-optical unit 335. In addition, the carrier plate 371 is spaced apart from the uppermost multi-aperture plate of the micro-optical unit 335 by the pitch D1. It may be for example more than 0.5 cm or more than 1 cm or 3 cm or 5 cm. The pitch D1 is in general structurally selectable and, if appropriate, also explicitly adjustable. It is also, by virtue of this relatively great pitch, possible to achieve greater protection of the micro-optical unit 335 of the micro-optical unit module 380.

In the exemplary embodiment shown according to FIGS. 3A-3B, furthermore the holding element for the carrier plate 371 is fixedly connected to the micro-optical unit holder 382 of the micro-optical unit 335 and in the case shown is integrated in the micro-optical unit holder 382. Specifically, the holding element for the carrier plate 371 is passed through the flange, via which the micro-optical unit holder 382 can be installed sealingly in a multiple particle beam system 1.

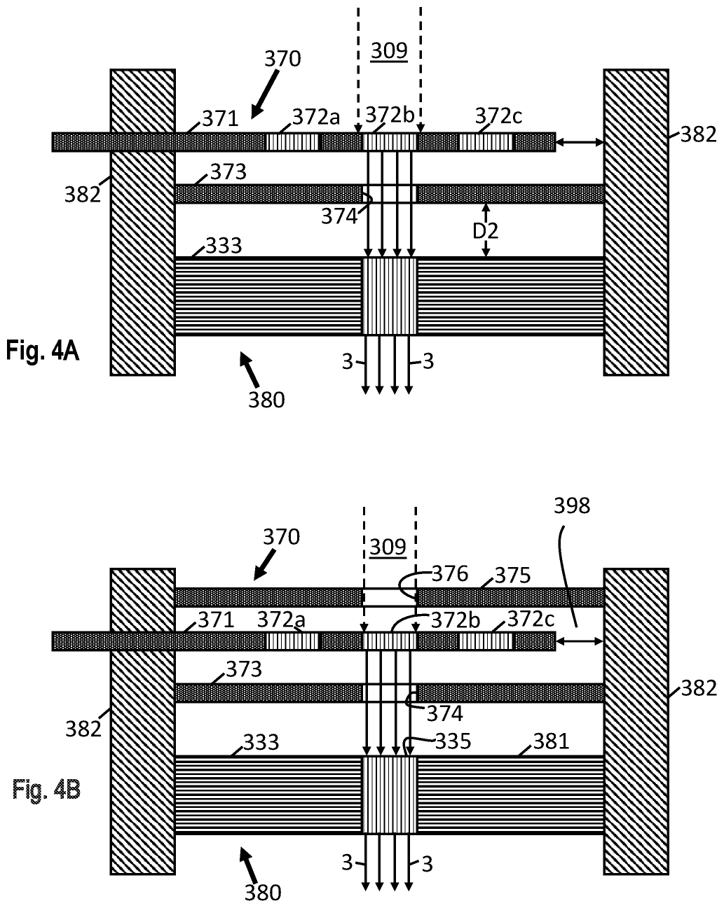

FIGS. 4A-4B schematically shows a further arrangement with a pre-aperture module 370 and with a micro-optical unit module 380. In FIG. 4A, the illustrated pre-aperture module 370 furthermore comprises a lower aperture plate 373 with a singular central opening 374. It is arranged in the particle-optical beam path between the carrier plate 371 and the micro-optical unit module 380 such that, during operation of the multiple particle beam system 1, the first individual particle beams 3 pass through the opening 374 in the lower aperture plate 373 without contact. In the example shown, the material of the lower aperture plate 373 is x-ray absorbing. It may comprise, for example, copper. The lower aperture plate 373 thus forms additional protection against x-ray radiation for the micro-optical unit module 380. The lower aperture plate can be approximately between 1.0 mm and 1.5 mm thick. In addition or as an alternative, it is possible for the lower aperture plate to have an x-ray absorbing coating. Such a coating can comprise for example a gold coating, for the thickness d_{AU} of which it holds true, for example, that 3 μm≤d_{AU}≤50 μm, such as 5 μm≤d_{AU}≤20 μm. The gold coating may be applied by sputtering or galvanically. In addition or as an alternative, it is also possible for the x-ray absorbing layer to have a thin film or layer comprising copper, tantalum and/or titanium, wherein for the thickness dₛ of this layer it holds true for example that 0.1 mm≤dₛ≤1.0 mm, such as 0.25 mm≤dₛ≤0.75 mm.

The arrangement, illustrated in FIG. 4B, with the pre-aperture module 370 and the micro-optical unit module 380 comprises, in addition to the lower aperture plate 373, an upper aperture plate 375 with a singular central opening 376. This upper aperture plate 375 is arranged in the particle-optical beam path above the carrier plate 371, with the result that the charged particles 309 from the particle source 301 completely or partially pass through the central opening 376 in the upper aperture plate 375. In the example shown, they completely pass through it. It is thus also the case in the example in FIG. 4b that secondary beams and in particular x-ray radiation are generated only when the illuminating beam 309 is incident on the multi-aperture array 372b. According to one embodiment of the disclosure, the material of the upper aperture plate 375 is x-ray absorbing. It may comprise, for example, copper. The thickness of the upper aperture plate can be at least 1 mm. In addition or as an alternative, it is possible for the upper aperture plate to have an x-ray absorbing coating. Such a coating can comprise for example a gold coating, for the thickness d_{AU} of which it holds true, for example, that 3 μm≤d_{AU}≤50 μm, such as 5 μm≤d_{AU}≤20 μm. The gold coating may be applied by sputtering or galvanically. In addition or as an alternative, it is also possible for the x-ray absorbing layer to have a thin film or layer comprising copper, tantalum and/or titanium, wherein for the thickness dₛ of this layer it holds true, for example, that 0.1 mm≤dₛ≤ 1.0 mm, such as 0.25 mm≤dₛ≤0.75 mm.

As already explained in connection with the exemplary embodiments in FIGS. 3A-3B, it is also the case in the exemplary embodiments illustrated in FIGS. 4A-4B that the carrier plate 371 is displaceable in the particle-optical beam path, with the result that exactly one multi-aperture array 372 of the carrier plate 371 is arranged actively in the particle-optical beam path and serves as filter array. This movement is illustrated in turn by the double-headed arrow in FIGS. 4A-4B.

In particular in FIG. 4B, it is evident that the upper aperture plate 375 and the lower aperture plate 373 form walls of a pre-aperture chamber 398. In this pre-aperture chamber 398, secondary particles are mostly absorbed. Also generated x-ray radiation is absorbed primarily by the walls of this pre-aperture chamber 398. The inner wall regions on the sides of the pre-aperture chamber 398 for this purpose can also be x-ray absorbing or have a corresponding coating.

According to an embodiment of the disclosure, the openings 376 and 374 in the upper aperture plate 375 and/or the lower aperture plate 373 are closable in vacuum-tight fashion, for example via a vacuum gate valve (not illustrated in FIGS. 4A-4B). This can afford advantages in exchanging the carrier plate 371 provided that the pre-aperture chamber 398 is accessible from outside the multiple particle beam system 1. In that case, specifically, it is possible to close and then ventilate the pre-aperture chamber, completely remove the carrier plate 371 and exchange it for a new carrier plate with a set of at least two identical multi-aperture arrays 372, re-evacuate the pre-aperture chamber 398 and bring selectively exactly one of the multi-aperture arrays 372, which have an identical action, or are identical, of the new carrier plate 371 into the particle-optical beam path. An exchange of the micro-optical unit module 380 can in this way be delayed even longer.

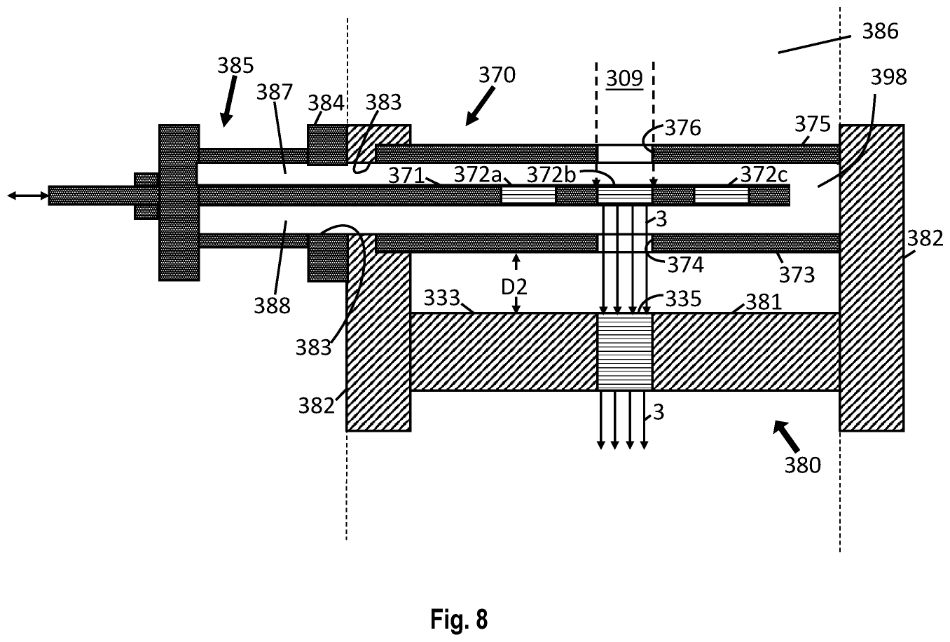

FIG. 8 shows, by way of example, such an example in which the pre-aperture chamber 398 comprises an outer region 385, which is accessible from the outside. After sealing the openings 376 and 374, by releasing the fastening region 384 the carrier plate 371 can be reached and exchanged separately.

The exemplary embodiments illustrated in FIGS. 3A-3B, 4A-4B and 8 show a carrier plate 371 which is displaceable linearly in a direction orthogonal to the particle-optical beam path. It is, however, of course also possible for the carrier plate 371 to be displaceable with two degrees of freedom within a plane oriented orthogonally to the particle-optical beam path. In addition, one option is for the carrier plate 371 to be displaceable along the direction of the particle-optical beam path (height adjustment). The latter facilitates use of the pre-aperture module 370 with any desired micro-optical unit modules 380.

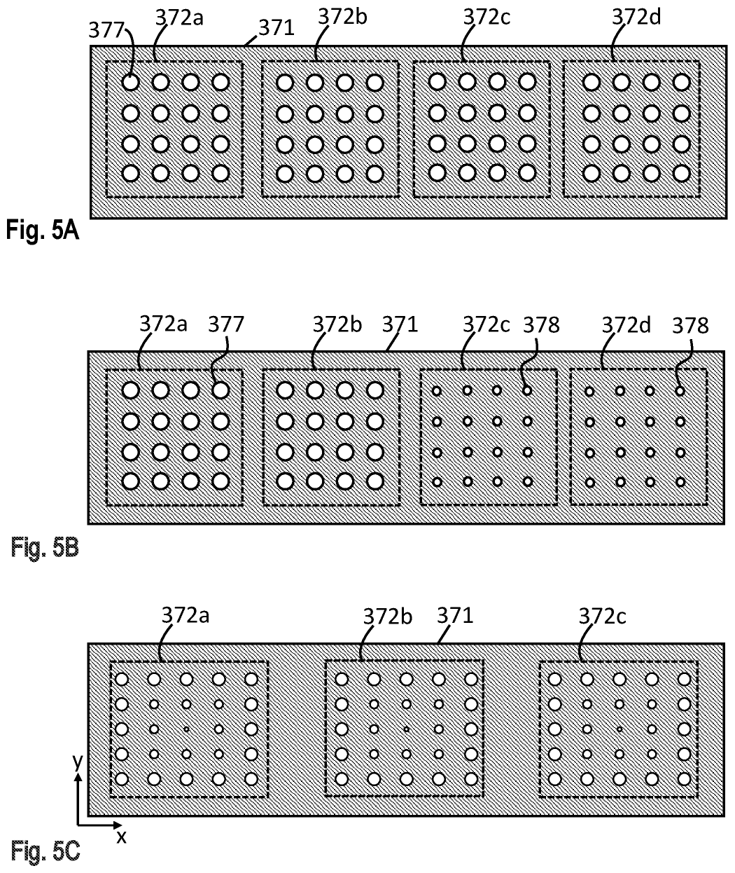

FIGS. 5A-5C schematically shows several examples of carrier plates 371: FIG. 5A shows a carrier plate 371 with a set which comprises four identical multi-aperture arrays 372a, 372b, 372c and 372d. Each multi-aperture array 372 comprises the same number N of apertures 377 (in the example illustrated, 16 apertures), the same shape and size of the apertures 377, and the same arrangement of the apertures 377. In the example shown, the apertures 377 are round and the 16 apertures 377 are overall arranged in the form of a square array 372. Of course, the array 372 could also be arranged differently, for example in the form of a rectangle, or it could be a hexagonal arrangement of apertures.

FIG. 5B shows a carrier plate 371 with a first set and with a second set. The first set comprises the multi-aperture arrays 372a and 372b. They are identical and have the same action. The second set comprises the multi-aperture arrays 372c and 372d. The number of apertures, the shape and the arrangement of the apertures are identical in both sets. However, in the two sets the aperture diameter is different: The apertures 377 in the first multi-aperture arrays 372a and 372b have a larger diameter than the apertures 378 in the multi-aperture arrays 372c and 372d of the second set. Multi-aperture arrays from different sets thus do not have the same action. Specifically, when a multi-aperture array 372a, 372b of the first set is in use, first individual particle beams 3 with a larger individual beam diameter and thus also with a higher individual beam current are created. Accordingly, when the multi-aperture arrays 372c, 372d are in use, they each create individual particle beams 3 with a smaller diameter and lower beam current. Using a filter plate 371 with different sets of identical multi-aperture arrays 372 thus makes it possible to have the effect that, on the one hand, the maintenance interval owing to an exchange due to x-ray radiation damage is prolonged, and that on the other hand there is a straightforward option for adjusting various beam currents in the multiple particle beam system 1.

FIG. 5C shows a further filter plate 371 which comprises a set with three identical multi-aperture arrays 372a, 372b and 372c. In the example illustrated, the apertures in the multi-aperture arrays 372a, 372b and 372c have a respective (identical) field profile. In the example shown, the aperture diameter is varied, specifically in two mutually independent directions x and y, or with a radial dependence on the minimal central opening in the multi-aperture arrays 372a, 372b and 372c. It is, however, of course also conceivable for a field profile to be Cartesian and exist only in one direction, for example for correction of an image plane tilt.

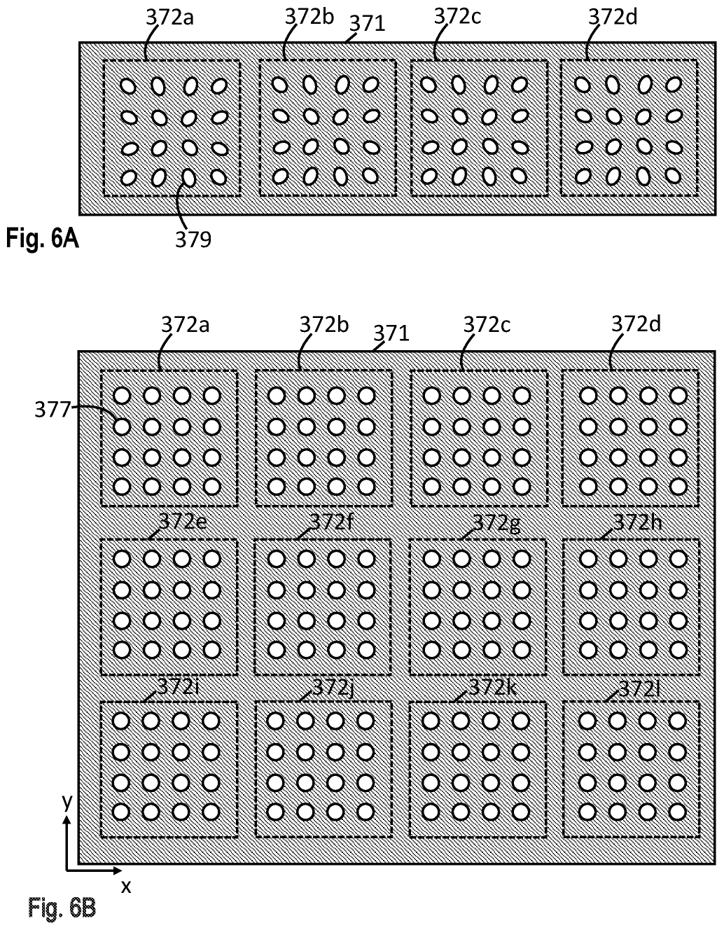

FIGS. 6A-6B schematically show further examples of carrier plates 371: FIG. 6A shows a carrier plate 371 with a set which comprises four identical multi-aperture arrays 372a to 372d. In the example shown, the apertures 379 are elliptical.

FIG. 6B shows a carrier plate 371 with a total of 12 multi-aperture arrays 372a to 372l. They are—by contrast to the previously described exemplary embodiments—not all arranged linearly one behind another, but rather are arranged two-dimensionally in the carrier plate 371. To use these multi-aperture arrays 372a to 372l, it is thus desirable for the carrier plate 371 of the pre-aperture module 370 to be displaceable in two mutually linearly independent directions x, y, which are arranged orthogonally to the particle-optical beam path. In the case of such a two-dimensional arrangement of multi-aperture arrays 372, it is also of course possible to provide different sets. For each set, it holds true that it comprises at least two identical multi-aperture arrays 372 with the same action.

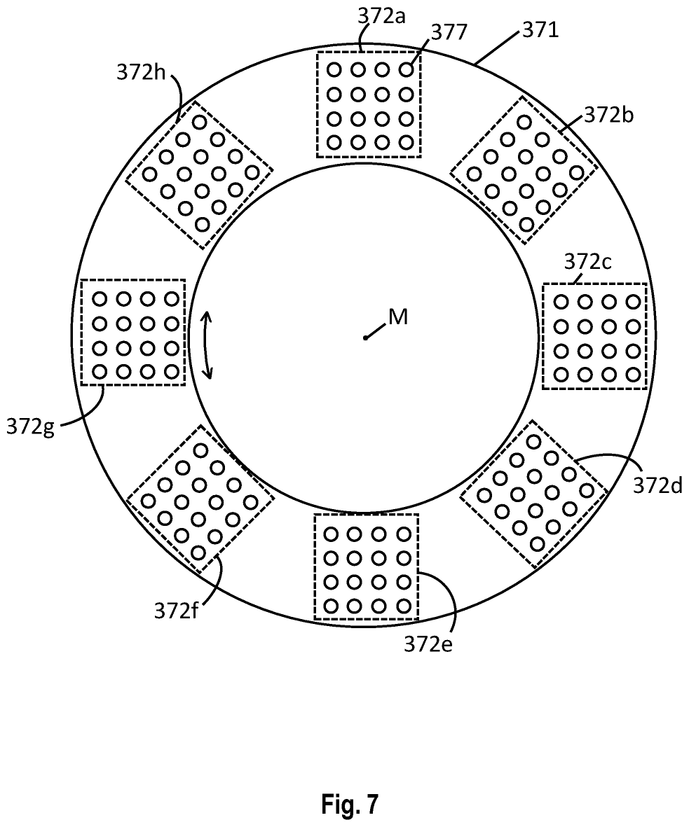

FIG. 7 schematically shows a further carrier plate 371 with identical multi-aperture arrays 372a to 372h. The multi-aperture arrays 372a to 372h are arranged on a circular ring in the example shown. By virtue of a circular movement around the midpoint M of the circular ring—indicated by the double-headed arrow—the multi-aperture arrays can each be introduced selectively and individually as an active multi-aperture array into the particle-optical beam path. The example illustrated thus involves a carousel solution. A revolver system solution is also conceivable with slight modifications.

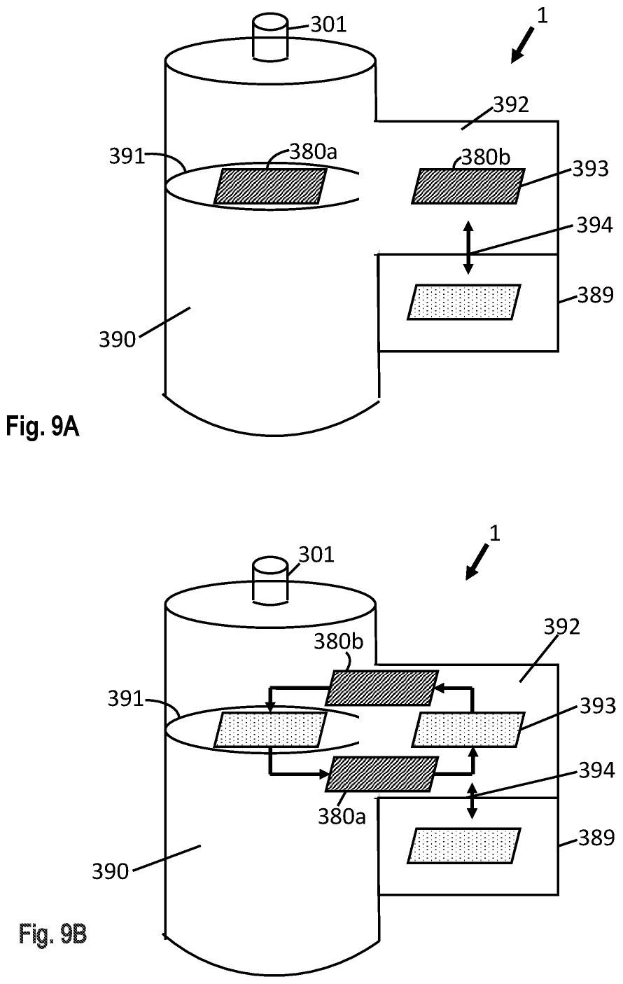

FIGS. 9A-9B schematically show a multiple particle beam system 1 with a storage chamber 392 for a micro-optical unit module 380. Specifically, the multiple particle beam system 1 comprises a column chamber 390, which is evacuated. Arranged inside the column is an operating position 391 for the micro-optical unit module 380. In FIG. 9A, located in this operating position 391 is the micro-optical module 380a. Outside the particle-optical beam path inside the storage chamber 392 is a further micro-optical unit module 380b. It is arranged in a storage position 393. The storage chamber 392 is, like the column chamber 390, evacuated, the two chambers 392 and 390 can be separate from one another or connected to one another. In any case, the further micro-optical unit module 380b is protected against particle beams in that the storage chamber 392 is outside the column chamber 390 and thus remote from the particle-optical beam path. In addition, it is protected against x-ray radiation, but that is not the main problem in the exemplary embodiment shown. Furthermore, the multiple particle beam system 1 comprises a lock chamber 389 with a lock 394 to the storage chamber 392.

The arrows in FIGS. 9A-9B now illustrate an exchange mechanism for exchanging the micro-optical unit module 380a for the further micro-optical unit module 380b: By virtue of a corresponding mechanism, which is indicated by the arrows in FIGS. 9A-9B, the micro-optical unit modules 380a and 380b can be moved one past the other and change places. The micro-optical unit module 380a can be brought from the operating position 391 into the storage position 393. Accordingly, the additional micro-optical unit module 380b can be brought from the storage position 393 into the operating position 391. This supply with at least one further micro-optical unit module 380b prolongs in turn the maintenance interval due to an exchange of the micro-optical unit module.

Instead of providing a separate lock chamber 389, it is also possible to provide the storage chamber 392 itself with an outer door. This simplifies the exchanging mechanism for the micro-optical unit module 380, but overall prolongs the time to completely exchange a micro-optical unit module 380: It is specifically possible, in the lock chamber 389 irrespective of the operation of the multiple particle beam system 1, to perform an evacuation and/or a ventilation operation. This saves on time.

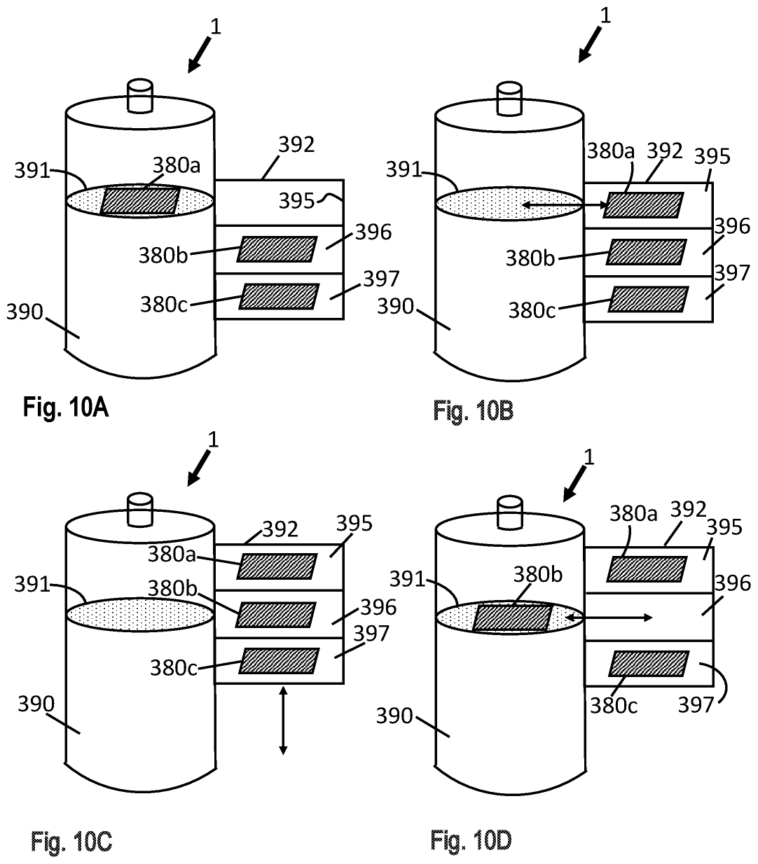

FIGS. 10A-10D show by way of example a further multiple particle beam system 1 with a storage chamber 392 for a multiplicity of micro-optical unit modules 380a, 380b and 380c. In the exemplary embodiment shown, the storage chamber 392 is divided into three compartments 395, 396 and 397. Each compartment 395, 396, 397 may contain a micro-optical unit module 380a, 380b, 380c, which may be arranged in a storage position. A micro-optical unit module 380 can then be exchanged as follows: Firstly, the storage chamber 392 is in a first position, as illustrated in FIG. 10A: The compartment 395 is at the level of the operating position 391 for a micro-optical unit module 380. Through a lock (not shown), the micro-optical unit module 380a from the compartment 395 can be introduced under vacuum into the column chamber 390 and arranged in the active operating position 391. Then, it is possible to bring the “spent” micro-optical unit module 380a back into the compartment 395. This is illustrated in FIG. 10B.

Then, the relative position of the storage chamber 392 can be changed with respect to the column chamber 390 containing the operating position 391 for the micro-optical unit module 380. This is indicated in FIG. 10C by the double-headed arrow in the vertical direction, or z direction. After this relative movement, the compartment 396 containing the micro-optical unit module 380b is now at the level of the operating position 391. Through a lock (not shown), the micro-optical unit module 380b can be brought into the operating position 391. This is illustrated in FIG. 10D.

The procedure can continue with the micro-optical unit module 380c in the compartment 397, and so on accordingly.

Other mechanisms for bringing a micro-optical unit module 380 into the column chamber 390 and the operating position 391 therein are also conceivable.

In general, it is possible, by stocking one or more micro-optical unit modules 380 already under vacuum, for a “spent” micro-optical unit module 380 to be exchanged more quickly for one of the stocked micro-optical unit modules 380. A stocked micro-optical unit module 380 is transferred into the operating position, qualified and aligned optionally during an inactive period of the multiple particle beam system, during which e.g. no measurement is performed.

Both in the case of the exemplary embodiments illustrated in FIGS. 9A-9B and in the case of the exemplary embodiments illustrated in FIGS. 10A-10D it is possible for the storage chamber 392 to have an outer door and/or for the storage chamber to have a vacuum and ventilation unit for generating a vacuum in the storage chamber 392 or ventilating the storage chamber 392. In addition, it is possible for the storage chamber 392 to furthermore have a heating element (not illustrated) for baking the storage chamber 392. In addition or as an alternative, the storage chamber 392 can have a plasma cleaning unit (not illustrated) for cleaning a stocked micro-optical unit module 380 and/or an exchanged micro-optical unit module 380. This makes it possible to remove for example secondary particles deposited on the micro-optical unit module 380 and use the micro-optical unit module for even longer.

Moreover, it is possible, according to the principles illustrated in FIGS. 9A-9B and 10A-10D, not only to stock and exchange a micro-optical unit module 380 according to the arrangement according to the disclosure of pre-aperture module 370 and micro-optical unit module 380, but also to stock and exchange the entire arrangement with the pre-aperture module 370 and the micro-optical unit module 380. As an alternative, instead of the arrangement according to the disclosure with the pre-aperture module 370 and the micro-optical unit module 380, it may also be a micro-optical unit arrangement or multi-aperture arrangement 305, as has been presented in connection with FIG. 2.

In all other respects, it holds true very generally that the described exemplary embodiments are not to be understood as limiting for the disclosure. Rather, they are only possible exemplary embodiments.

The disclosure discloses a multiple particle beam system 1 with an arrangement comprising a pre-aperture module 370 and a micro-optical unit module 380. The pre-aperture module 370 comprises a carrier plate 371 with a first set comprising at least two multi-aperture arrays 372 which are identical and thus have the same action, and have the same number N of apertures, the same shape and size of the apertures and the same arrangement of the apertures and thus can be exchanged one for another. A mechanism for arranging the carrier plate 371 in the particle-optical beam path makes it possible, in the event of damage to the active multi-aperture array in particular owing to x-ray radiation, to exchange multi-aperture arrays that have the same action. The micro-optical unit module 380, which is arranged downstream of the pre-aperture module 370 in the particle-optical beam path, is thereby protected better against x-ray radiation that occurs, and has a longer service life. Maintenance intervals of the multiple particle beam system 1 can be prolonged.

### LIST OF REFERENCE SIGNS

1 Multiple particle beam system, multi-beam particle microscope
3 Primary particle beams, first individual particle beams
5 Beam spots, incidence locations
7 Object, sample, wafer
9 Secondary particle beams, second individual particle beams
10 Computer system, controller
15 Sample surface, wafer surface
25 Image point of a second individual particle beam
81 Multi-pole electrode
82 Ring electrode
83 Spacer
84 Ring electrode
85 Aperture
86 Spacer
99 Absorbing and conducting layer
101 Object plane
102 Objective lens
103 Field lens
105 Axis
108 Crossover
200 Detector system
205 Projection lens system
206 Projection lens
207 Multi-particle detector
208 Projection lens
209 Projection lens
210 Projection lens
212 Crossover
214 Aperture filter, contrast stop
222 Collective anti-deflection system
300 Beam generating apparatus
301 Particle source
303 Collimation lens system
304 Multi-aperture array, filter plate
305 Micro-optical unit, multi-aperture arrangement, multi-beam particle generator
306 Multi-aperture plate
307 Field lens, aperture plate
308 Field lens
309 Particle beam
310 Multi-aperture plate
32 Intermediate image plane
323 Beam foci
333 Holding region
335 Membrane region
351 Aperture
370 Pre-aperture module
371 Carrier plate
372 Multi-aperture array
373 Lower aperture plate
374 Singular opening
375 Upper aperture plate
376 Singular opening
377 Round aperture
378 Round aperture
379 Elliptical aperture
380 Micro-optical unit module
381 Sequence of multi-aperture plates
382 Micro-optical unit holder
383 Feedthrough
384 Fastening region
385 Outer region
386 Vacuum chamber
387 Vacuum chamber
388 Vacuum chamber
389 Lock chamber
390 Column chamber
391 Operating position for micro-optical unit/micro-optical unit module
392 Storage chamber
393 Storage position
394 Lock
395 Compartment
396 Compartment
397 Compartment
400 Beam splitter, magnet arrangement
500 Scan deflector
600 Displacement stage or positioning device
X Direction
y Direction
Z Direction
M Centre

What is claimed is:

1. A multiple particle beam system, comprising:
a particle source configured to emit charged particles;
a pre-aperture module comprising:
a carrier plate comprising a first set of multi-aperture arrays, the first set of multi-aperture arrays comprising two identical multi-aperture arrays, the two identical multi-aperture arrays comprising the same number of apertures and the same arrangement of apertures, the apertures of the two identical multi-aperture arrays having the same shape and the same size;
a holding element configured to hold the carrier plate; and
a mechanism configured to displace the carrier plate in a particle-optical beam path to exchange the two identical multi-aperture arrays for each other in the particle-optical beam path;
a micro-optical unit module downstream of the pre-aperture module along the particle-optical beam path, the micro-optical unit comprising a multiplicity multi-aperture plates fixed relative to one another; and
a micro-optical unit holder configured to hold the multi-aperture plates,
wherein, the multiple particle beam system is configured so that during operation of the multiple particle beam system:
the charged particles emitted by the particle source are incident on only one of the two identical multi-aperture arrays and pass through the carrier plate to form a multiplicity of first individual particle beams;
for each aperture of the multi-aperture plates, exactly one of the first individual particle beams passes through the aperture;
the micro-optical unit particle-optically shapes the multiplicity of first individual particle beams.

2. The multiple particle beam system of claim 1, wherein the micro-optical unit comprises a multi-stigmator unit, and/or the micro-optical unit comprises a multi-lens array.

3. The multiple particle beam system of claim 1, wherein the multiple particle beam system is configured so that, during operation of the multiple particle beam system, the multiplicity multi-aperture plates comprises a first multi-aperture plate in the particle-optical beam path through which the first individual particle beams formed in the pre-aperture module pass without contacting apertures in the first multi-aperture plate.

4. The multiple particle beam system of claim 1, wherein the holding element is fixed to the micro-optical unit holder, or the holding element is integrated in the micro-optical unit holder.

5. The multiple particle beam system of claim 1, wherein the micro-optical unit holder comprises a flange configured to seal the micro-optical unit holder in the multiple particle beam system.

6. The multiple particle beam system of claim 5, the flange passes through the holding element.

7. The multiple particle beam system of claim 1, wherein the pre-aperture module further comprises a lower aperture plate comprising a singular central opening in the particle-optical beam path between the carrier plate and the micro-optical unit module so that, during operation of the multiple particle beam system, the first individual particle beams pass through the singular central opening without contacting the singular central opening.

8. The multiple particle beam system of claim 7, wherein the lower aperture plate comprises an x-ray absorbing material.

9. The multiple particle beam system of claim 7, wherein a pitch between the lower aperture plate and an uppermost multi-aperture plate of the micro-optical unit module is at least 0.5 centimeter.

10. The multiple particle beam system of claim 1, wherein the pre-aperture module further comprises an upper aperture plate comprising a singular central opening in the particle-optical beam path upstream the carrier plate so that, during use of the multiple particle beam system, the charged particles from the particle source at least partially pass through the singular central opening.

11. The multiple particle beam system of claim 10, the upper aperture plate comprises an x-ray absorbing material.

12. The multiple particle beam system of claim 1, wherein:
the pre-aperture module further comprises a lower aperture plate and an upper aperture plate;
the lower aperture plate comprises a first singular central opening in the particle-optical beam path between the carrier plate and the micro-optical unit module so that, during operation of the multiple particle beam system, the first individual particle beams pass through the singular central opening without contacting the first singular central opening;
the upper aperture plate comprises a second singular central opening in the particle-optical beam path upstream the carrier plate so that, during use of the multiple particle beam system, the charged particles from the particle source at least partially pass through the second singular central opening;
the upper aperture plate and the lower aperture plate define walls of a pre-aperture chamber for the carrier plate; and
the first and second singular central openings are closable in vacuum-tight fashion.

13. The multiple particle beam system of claim 12, wherein the multiple particle beam system is configured so that the pre-aperture chamber is accessible from outside the multiple particle beam system.

14. The multiple particle beam system of claim 1, wherein the carrier plate is linearly displaceable linearly in a direction orthogonal to the particle-optical beam path.

15. The multiple particle beam system of claim 1, wherein the carrier plate is displaceable in two degrees of freedom within a plane orthogonal to the particle-optical beam path.

16. The multiple particle beam system of claim 1, wherein the carrier plate is displaceable along the direction of the particle-optical beam path.

17. The multiple particle beam system of claim 1, wherein the two identical multi-aperture arrays are introducible into the particle-optical beam path via a carousel or revolver system.

18. The multiple particle beam system of claim 1, wherein the apertures in the two identical multi-aperture arrays comprises apertures that are round, apertures that are elliptical, and/or apertures that have a field profile.

19. The multiple particle beam system of claim 1, wherein:
the carrier plate comprises a second set of multi-aperture arrays;
the second set of multi-aperture arrays comprises two identical multi-aperture arrays;
the two identical multi-aperture arrays of the second set of multi-aperture arrays comprise the same number of apertures and the same arrangement of apertures;
the apertures of the two identical multi-aperture arrays of the second set of multi-aperture arrays have the same shape and the same size; and
apertures in the two identical multi-aperture arrays of the second set of multi-aperture arrays differ from the apertures in the two identical multi-aperture arrays of the first set of multi-aperture arrays.

20. The multiple particle beam system of claim 1, further comprising:
a further micro-optical unit module inside a vacuum but outside the particle-optical beam; and
an exchanging mechanism configured to exchange the micro-optical unit module for the further micro-optical unit module under vacuum.

21. The multiple particle beam system of claim 20, further comprising a storage chamber in which the further micro-optical unit module is disposed, wherein the storage chamber is separated from the vacuum via a lock.

22. The multiple particle beam system of claim 21, wherein:
the storage chamber comprises an outer door; and/or
the storage chamber comprises a vacuum and ventilation unit configured to generate a vacuum in the storage chamber or to ventilate the storage chamber.

23. The multiple particle beam system of claim 21, wherein:
the storage chamber furthermore comprises a heating element configured to heat the micro-optical unit module; and/or
the storage chamber comprises a plasma cleaning unit configured to clean a stocked micro-optical unit module and/or an exchanged micro-optical unit module.
